(19) United States
(12) Patent Application Publication
(10) Pub. No.: US 2012/0269970 A1
(43) Pub. Date: Oct. 25, 2012

(54) CLEANING METHOD AND FILM DEPOSITING METHOD

(75) Inventors: Yasuyuki IDO, Yamanashi (JP); Kippei Sugita, Yamanashi (JP); Tatsuya Yamaguchi, Yamanashi (JP)

(73) Assignee: Tokyo Electron Limited, Tokyo (JP)

(21) Appl. No.: 13/429,564

(22) Filed: Mar. 26, 2012

(30) Foreign Application Priority Data
Mar. 29, 2011 (JP) 2011-073192

(51) Int. Cl. C23C 16/455; B08B 7/04; B08B 9/08

(52) U.S. Cl. 427/255.394; 134/19

(57) ABSTRACT

A cleaning method for a film deposition apparatus that deposits a polyimide film conveyed into a film deposition chamber by feeding a first source gas formed of dianhydride and a second source gas formed of diamine into the film deposition chamber, the method including the steps of: generating an oxygen atmosphere in the film deposition chamber, and removing polyimide remaining in the film deposition chamber by heating the film deposition chamber at a temperature of 360° C. to 540° C. in the oxygen atmosphere and oxidizing the polyimide.

### CROSS-REFERENCE TO RELATED APPLICATION

The present application is based upon and claims the benefit of priority of Japanese Patent Application No. 2011-073192, filed on Mar. 29, 2011, the entire contents of which are incorporated herein by reference.

### BACKGROUND OF THE INVENTION

1. Field of the Invention

The present invention relates to a cleaning method for a film deposition apparatus for depositing a film on a substrate and a film depositing method for depositing the film on the substrate.

2. Description of the Related Art

In recent years, a wide range of materials from inorganic materials to organic materials are used for a semiconductor device. The characteristics of the organic materials (which inorganic materials do not have) help to optimize the properties of the semiconductor device and the manufacturing process of the semiconductor device.

One of the organic materials is polyimide. Polyimide has a high insulating property. Therefore, a polyimide film obtained by depositing polyimide on a surface of a substrate can be used as an insulating film, and as an insulating film of a semiconductor device.

For depositing the polyimide film, there is a known film deposition method where vapor deposition polymerization is performed by using, for example, pyromellitic dianhydride (PMDA) and 4,4′-oxydianiline (ODA) as raw material monomers. Vapor deposition polymerization is a method that causes thermal polymerization of pyromellitic dianhydride (PMDA) and 4,4′-oxydianiline (ODA) (being used as raw material monomers) on a surface of a substrate (see, for example, Japanese Patent No. 4283910). Japanese Patent No. 4283910 discloses a film deposition method where a polyimide film is deposited by vaporizing PMDA and ODA monomers in a vaporizer, feeding each of the vaporized gases to a vapor deposition polymerization chamber, and causing vapor deposition polymerization on a substrate.

The method for depositing the polyimide film by vapor deposition requires a cleaning step for removing polyimide adhered to the film deposition chamber during a film deposition process. For example, Japanese Laid-Open Patent Publication No. 9-255791 discloses a method of thermally decomposing adhered polyimide by heating the film deposition chamber with a heating mechanism. Further, there is a thermal decomposition method of heating polyimide inside an oxygen containing atmosphere (see, for example, Japanese Laid-Open Patent Publication No. 2006-169344).

However, the cleaning step (i.e. removing polyimide adhered to the film deposition chamber by which a polyimide film is deposited) has the following problems.

In a case of heating in a state where oxygen is blocked out, organic compounds containing polyimide are only thermally decomposed. Therefore, the organic compounds containing polyimide are carbonized and remain in the form of carbon. The remaining carbon becomes the cause of particles generated in the film deposition apparatus. Accordingly, in a case where a film deposition process is performed in such film deposition apparatus, particles adhere to the substrate on which the polyimide film is deposited. Then, the substrate having particles adhered thereto may be determined to be defective during an inspecting step. Thus, the yield of the film deposition apparatus decreases.

Further, even in a case where the cleaning step is performed in an oxygen containing atmosphere, if heating is performed in a state where only a small amount of oxygen is being supplied, organic compounds containing polyimide are only thermally decomposed. Therefore, the organic compounds containing polyimide are carbonized and remain in the form of carbon.

### SUMMARY OF THE INVENTION

In view of the above, an embodiment of the present invention provides a cleaning method and a film depositing method for preventing carbonizing of polyimide and removing polyimide without any particles remaining a film deposition chamber.

According to an embodiment of the present invention, there is provided a cleaning method for a film deposition apparatus that deposits a polyimide film conveyed into a film deposition chamber by feeding a first source gas formed of dianhydride and a second source gas formed of diamine into the film deposition chamber, the method including the steps of: generating an oxygen atmosphere in the film deposition chamber; and removing polyimide remaining in the film deposition chamber by heating the film deposition chamber at a temperature of 360 to 540° C. in the oxygen atmosphere and oxidizing the polyimide.

According to another embodiment of the present invention, there is provided a film depositing method for depositing a film on at least a substrate by feeding source gases into a film deposition chamber, the method including the steps of: performing a film depositing process including conveying in the substrate to the film deposition chamber, feeding an adhesion accelerating agent gas into the film deposition chamber, treating a surface of the substrate with the adhesion accelerating agent gas, depositing a polyimide film on the substrate by feeding a first source gas formed of dianhydride and a second source gas formed of diamine into the film deposition chamber, and conveying out the substrate having the polyimide film deposited thereon from the film deposition chamber; and performing a cleaning process including generating an oxygen atmosphere in the film deposition chamber, and removing polyimide remaining in the film deposition chamber by heating the film deposition chamber in the oxygen atmosphere and oxidizing the polyimide.

The object and advantages of the present invention will be realized and attained by means of the elements and combinations particularly pointed out in the claims.

It is to be understood that both the foregoing general description and the following detailed description are exemplary and explanatory and not restrictive of the invention as claimed.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention, in which:

FIG. 1 is a schematic longitudinal cross-sectional view of a film deposition apparatus used for performing a cleaning method and a film depositing method according to a first embodiment of the present invention;

FIG. 2 is a schematic perspective view of a loading area according to an embodiment of the present invention;

FIG. 3 is a perspective view of a boat according to an embodiment of the present invention;

FIG. 4 is a cross-sectional view of a configuration of a film deposition chamber according to an embodiment of the present invention;

FIG. 5 is a schematic diagram illustrating a configuration of an adhesion accelerating agent feed mechanism according to an embodiment of the present invention;

FIG. 6 is a flowchart for illustrating processes of steps including a film deposition process using the film deposition apparatus according to the first embodiment of the present invention;

FIGS. 7A and 7B illustrate an example where a silane coupling agent is used as an adhesion accelerating agent according to an embodiment of the present invention;

FIGS. 8A-8B illustrate the manner in which polyimide is thermally decomposed and the manner in which polyimide is oxidized.

FIGS. 9A and 9B are graphs illustrating the results of measuring the quantity of a generated gas (generation quantity) by using a mass spectrometry (MS) method in a case of using a Temperature Programmed Desorption (TPD) method where the gas is desorbed by increasing the temperature of polyimide;

FIG. 10 is a cross-sectional view illustrating a state before and after performing the cleaning process on a wafer having a layered member formed thereon;

FIG. 11 is a plan view illustrating a film deposition apparatus for performing a cleaning method and a film depositing method according to a second embodiment of the present invention;

FIG. 12 is a front view illustrating configurations of a process container, an adhesion accelerating agent feed mechanism, and an exhaust mechanism according to an embodiment of the present invention; and

FIG. 13 is a plan view illustrating configurations of a film deposition chamber, a feed mechanism, and an exhaust mechanism according to an embodiment of the present invention.

### DETAILED DESCRIPTION OF THE PREFERRED EMBODIMENT

Next, a description is given of embodiments of the present invention with reference to the accompanying drawings.

### First Embodiment

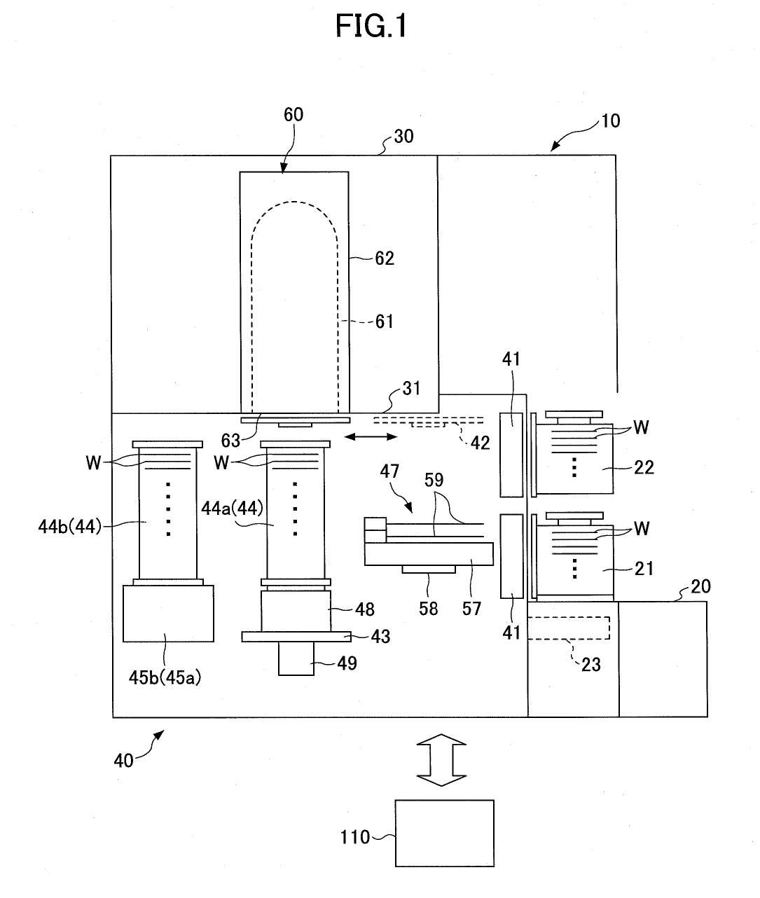

First, a description is given, with reference to FIG. 1 through FIG. 10, of a cleaning method and a film depositing method according to the first embodiment of the present invention.

The film depositing method according to this embodiment may be applied to a film deposition apparatus configured to deposit a polyimide film on a substrate held in a film deposition chamber by feeding the substrate with a first raw material gas, which is, for example, vaporized pyromellitic dianhydride (hereinafter abbreviated as “PMDA”), and a second raw material gas, which is, for example, vaporized 4,4′-3 oxydianiline (hereinafter, abbreviated as “ODA”).

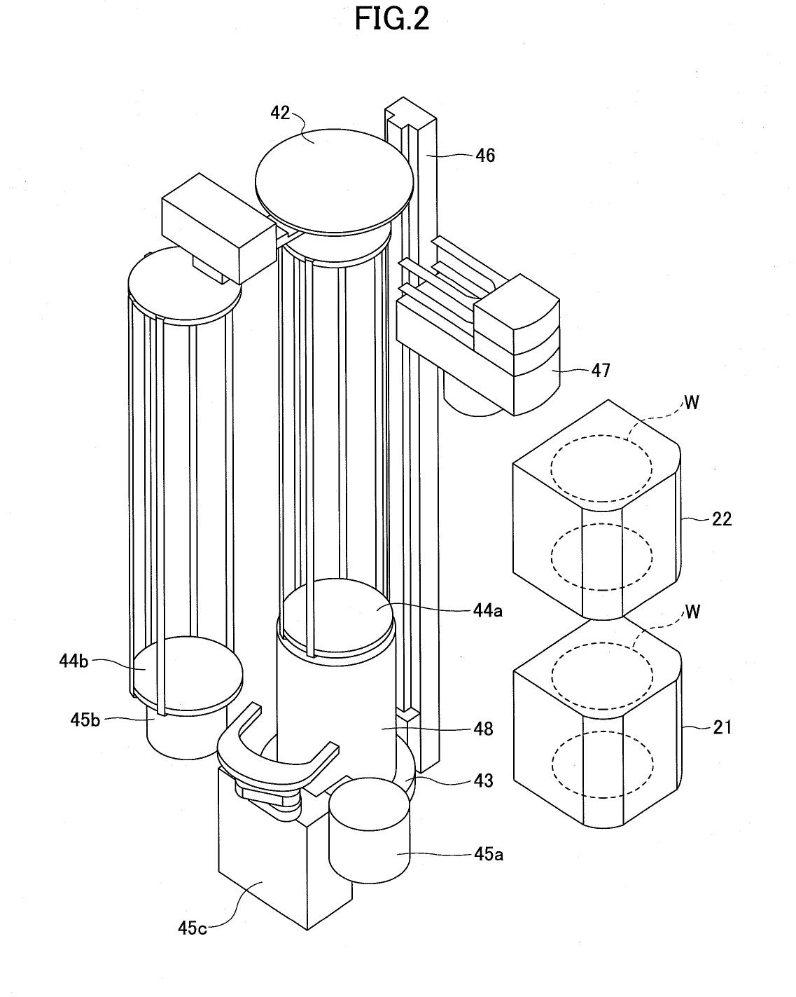

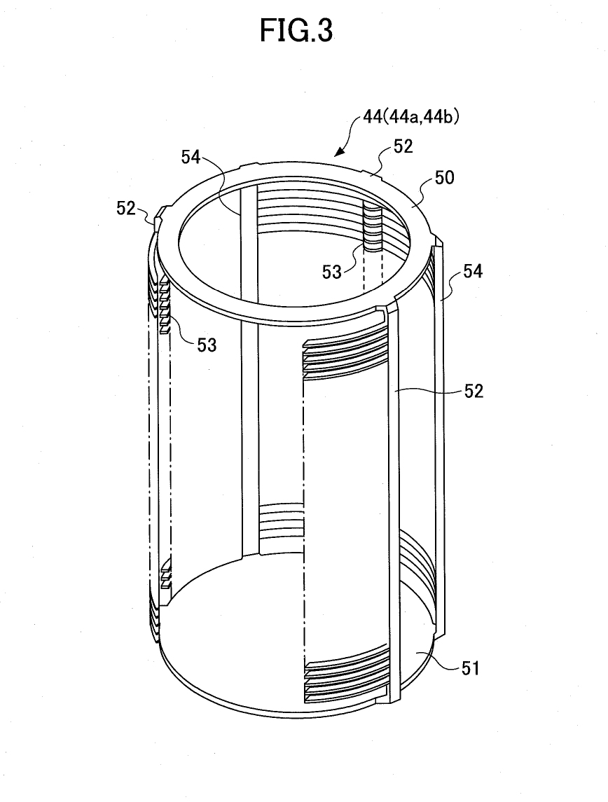

FIG. 1 is a schematic longitudinal cross-sectional view illustrating a film deposition apparatus 10 for performing the cleaning method and the film depositing method according to this embodiment. FIG. 2 is a schematic perspective view of a loading area 40. FIG. 3 is a perspective view illustrating an example of a boat 44.

The film deposition apparatus 10 includes a placement table (load port) 20, a housing 30, and a control part 110.

The placement table 20 is provided on the front side of the housing 30. The housing 30 includes the loading area (work area) 40 and the film deposition chamber 60. The loading area 40 is provided in a lower part of the housing 30. The film deposition chamber 60 is provided above the loading area 40 in the housing 30. Further, a base plate 31 is provided between the loading area 40 and the film deposition chamber 60. The below-described feeding mechanism 70 is provided in a manner connected to the film deposition chamber 60.

The base plate 31 is, for example, a stainless steel base plate for providing a reaction tube 61 of the film deposition chamber 60. An opening, which is not graphically illustrated, is formed in the base plate 31 to allow insertion of the reaction tube 61 from bottom up.

The placement table 20 is for carrying the wafers W into and out of the housing 30. Containers 21 and 22 are placed on the placement table 20. The containers 21 and 22 are closable containers (front-opening unified pods or FOUPs) having a detachable lid, which is not graphically illustrated, on the front and accommodate multiple, for example, approximately 50 wafers at predetermined intervals.

Further, an aligning unit (aligner) 23 configured to align notched parts (notches) provided in the peripheries of the wafers W transferred by the below-described transfer mechanism 47 in a single direction may be provided below the placement table 20.

The loading area 40 is a work area for transferring the wafers W between the containers 21, 22 and the boat 44, carrying (loading) the boat 44 into the film deposition chamber 60, and carrying out (unloading) the boat 44 from the film deposition chamber 60. Door mechanisms 41, a shutter mechanism 42, a lid body 43, the boat 44, bases 45a and 45b, an elevation mechanism 46, and the transfer mechanism 47 are provided in the loading area 40.

It is to be noted that the lid body 43 and the boat 44 may correspond to a substrate holding part according to an aspect of the present invention.

The door mechanisms 41 are configured to remove the lids of the containers 21 and 22 to cause the containers 21 and 22 to communicate with and be open to the inside of the loading area 40.

The shutter mechanism 42 is provided in an upper part of the loading area 40. The shutter mechanism 42 is so provided as to cover (or close) the below-described opening 63 of the film deposition chamber 60 to control or prevent a release of the heat inside the film deposition chamber 60 at high temperature to the loading area 40 through the opening 63 when the lid body 43 is open.

The lid body 43 includes a heat insulating tube 48 and a rotation mechanism 49. The heat insulating tube 48 is provided on the lid body 43. The heat insulating tube 48 prevents the boat 44 from being cooled through a transfer of heat with the lid body 43, and keeps heat in the boat 44. The rotation mechanism 49 is attached to the bottom of the lid body 43. The rotation mechanism 49 causes the boat 44 to rotate. The rotating shaft of the rotation mechanism 49 is so provided as to pass through the lid body 43 in a hermetic manner to rotate a rotating table, not graphically illustrated, provided on the lid body 43.

The elevation mechanism 46 drives the lid body 43 to move up and down when the boat 44 is carried into the film deposition chamber 60 from the loading area 40 and out of the film deposition chamber 60 to the loading area 40. The lid body 43 is so provided as to come into contact with the opening 63 to hermetically close the opening 63 when the lid body 43, moved upward by the elevation mechanism 46, has been carried into the film deposition chamber 60. The boat 44 placed on the lid body 43 may hold the wafers W in the film deposition chamber 60 in such a manner as to allow the wafers W to rotate in a horizontal plane.

The film deposition apparatus 10 may have multiple boats 44. In this embodiment, a description is given below, with reference to FIG. 2, of a case where the film deposition apparatus 10 includes two boats 44a and 44b, which may also be collectively referred to as the “boat 44” when there is no need to make a distinction between the boats 44a and 44b in particular.

The boats 44a and 44b are provided in the loading area 40. The bases 45a and 45b and a boat conveying mechanism 45c are provided in the loading area 40. The bases 45a and 45b are placement tables onto which the boats 44a and 44b are transferred from the lid body 43, respectively. The boat conveying mechanism 45c transfers the boats 44a and 44b from the lid body 43 to the bases 45a and 45b, respectively.

The boats 44a and 44b are made of, for example, quartz, and are configured to have the wafers W, which are large, for example, 300 mm in diameter, loaded in a horizontal position at predetermined intervals (with predetermined pitch width) in a vertical direction. For example, as illustrated in FIG. 3, the boats 44a and 44b have multiple, for example, three columnar supports 52 are provided between a top plate 50 and a bottom plate 51. The columnar supports 52 are provided with claw parts 53 for holding the wafers W. Further, auxiliary columns 54 may suitably be provided together with the columnar supports 52.

The transfer mechanism 47 is configured to transfer the wafers W between the containers 21 and 22 and the boats 44 (44a and 44b). The transfer mechanism 47 includes a base 57, an elevation arm 58 and plural forks (transfer plates) 59. The base 57 is so provided as to be vertically movable and turnable. The elevation arm 58 is, for example, so provided as to be vertically movable (movable upward and downward) with a ball screw or the like. The base 57 is so provided as to be horizontally movable (turnable) relative to the elevation arm 58.

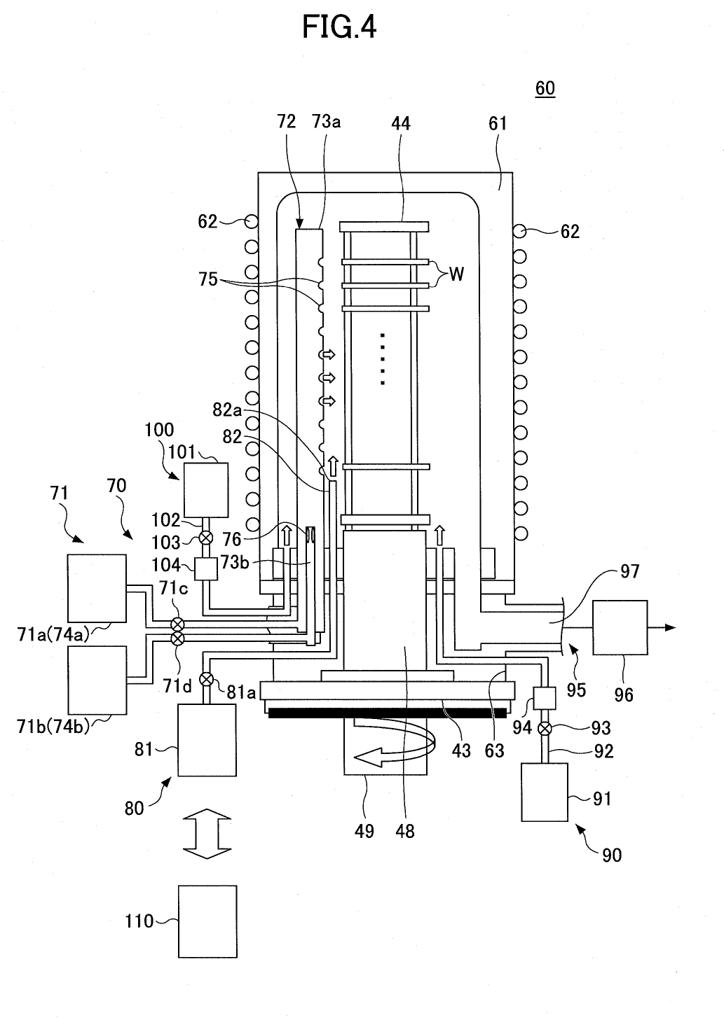

FIG. 4 is a cross-sectional view illustrating a configuration of the film deposition chamber 60 according to an embodiment of the present invention.

The film deposition chamber 60 may be, for example, a vertical furnace that accommodates multiple substrates to be processed (treated), such as thin disk-shaped wafers W, and performs a predetermined process such as CVD on the substrates to be processed. The film deposition chamber 60 includes the reaction tube 61, a heater 62, a cooling mechanism 65, a feed mechanism 70, adhesion accelerating agent feed mechanism 80, a purge gas feed mechanism 90, an exhaust mechanism 95, and a cleaning gas feed mechanism 100.

It is to be noted that the heater 62 may correspond to a heating mechanism according to an aspect of the present invention.

The reaction tube 61 is made of, for example, quartz, has a vertically elongated shape, and has the opening 63 formed at the lower end. The heater (heating apparatus) 62 is so provided as to cover the periphery of the reaction tube 61, and may control heating so that the inside of the reaction tube 61 is heated to a predetermined temperature, for example, 50° C. to 1200° C.

The feed mechanism 70 includes a source gas feeding part 71 and an injector 72 provided inside the film deposition chamber 60. The injector 72 includes a feeding tube 73a. The source gas feeding part 71 is connected to the feeding tube 73a of the injector 72.

In this embodiment, the feed mechanism 70 may include a first source gas feeding part 71a and a second source gas feeding part 71b. The first and the second source gas feeding parts 71a, 71b are connected to the injector 72 (feeding tube 73a) via valves 71c, 71d, respectively. The first source gas feeding part 71a includes a first vaporizer 74a configured to vaporize, for example, a PMDA source material. Thus, the first source gas feeding part 71a can feed PMDA gas. The second source gas feeding part 71b includes a second vaporizer 74b configured to vaporize, for example, an ODA source material.

A feeding hole 75 is formed in the feeding tube 73a as an opening toward the inside of the film deposition chamber 60. The injector 72 feeds the first and the second source gases flowing from the source gas feeding part 71 to the feeding tube 73a into the film deposition chamber 60 via the feeding hole 75.

Further, the feeding tube 73a may be provided in a manner extending in a vertical direction. Additionally, plural feeding holes 75 may be formed in the feeding tube 73a. The feeding hole 75 may have various shapes such as a circular shape, an elliptical shape, or a rectangular shape.

It is preferable for the injector 72 to include an inner feeding tube 73b. The inner feeding tube 73b may be formed in a portion that is upstream than a portion which the feeding hole of the feeding tube 73a is formed. Further, an opening 76 may be formed in the vicinity of a downstream side of the inner feeding tube 73b for feeding either the first or the second source gas to the inner space of the feeding tube 73a. With the inner feeding tube 73b having the above-described configuration, the first and the second source gases can be sufficiently mixed inside the inner space of the feeding tube 73a prior to feeding the first and the second source gases from the feeding hole 75 to the inside of the film deposition chamber 60.

The following embodiment is a case where the first source gas is fed to the feeding tube 73a and the second source gas is fed to the inner feeding tube 73b. Alternatively, the first source gas may be fed to the inner feeding tube 73b, and the second source gas may be fed to the feeding tube 73a.

The opening 76 may have various shapes such as a circular shape, an elliptical shape, or a rectangular shape.

In this embodiment, the boat 44 may have multiple wafers W vertically accommodated therein at predetermined intervals. In this embodiment, the feeding tube 73a and the inner feeding tube 73b may be provided in a manner extending in a vertical direction. Further, assuming that a lower part of the feeding tube 73a corresponds to an upstream side and an upper part of the feeding tube 73a corresponds to a downstream side, the inner feeding tube 73b may be installed inside the feeding tube 73a in a position lower than the part which the feeding hole of the feeding tube 73a is formed. Further, the opening 76 for communicating with the inner space of the feeding tube 73a may be provided in the vicinity of an upper end part of the inner feeding tube 73b.

The feed mechanism 70 is configured to have, for example, the first source gas flow through the feeding tube 73a and the second source gas flow through the inner feeding tube 73b. The second source gas flows from the inner feeding tube 73b to the feeding tube 73a via the opening 76. Thereby, the first and the second source gases are mixed. In such mixed state, the first and the second source gases are fed into the film deposition chamber 60 via the feeding hole 75.

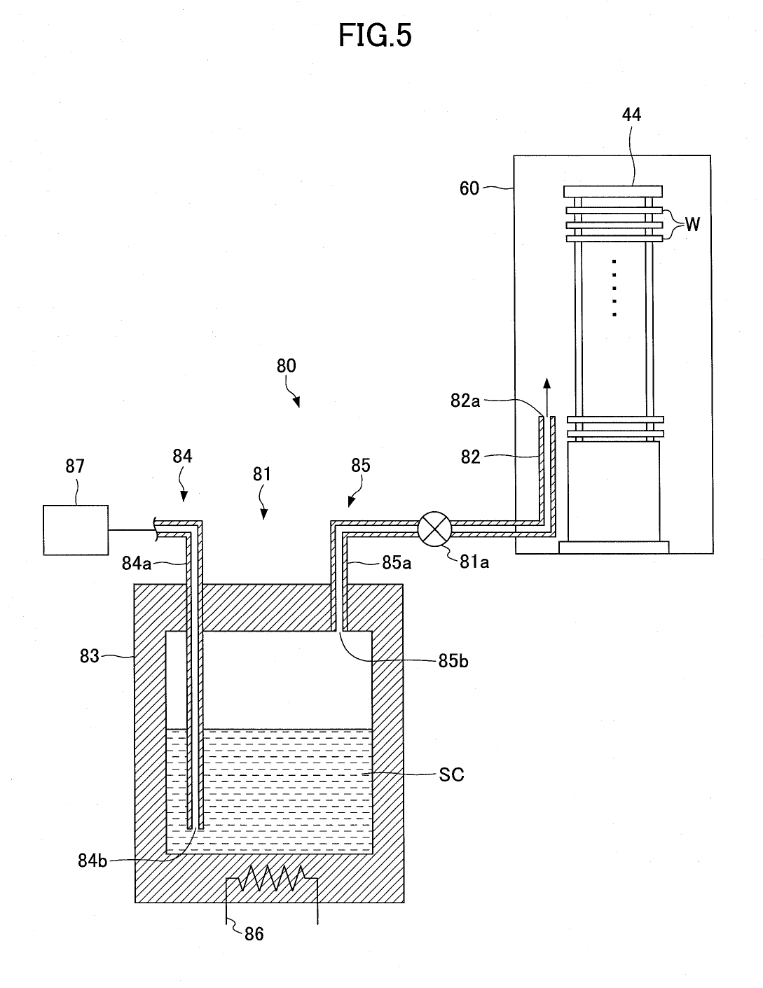

FIG. 5 is a schematic diagram illustrating a configuration of an adhesion accelerating agent feed mechanism 80 according to an embodiment of the present invention. It is to be noted that components other than those of the film deposition chamber 60, the boat 44, and the adhesion accelerating agent feed mechanism 80 are not illustrated in FIG. 5.

As illustrated in FIG. 5, the adhesion accelerating agent feed mechanism 80 includes a vaporizer 81 and a feeding tube 82 provided inside the film deposition chamber 60. The vaporizer 81 is connected to the feeding tube 82 via a valve 81a. The adhesion accelerating agent feed mechanism 80 feeds an adhesion accelerating agent gas (formed by vaporizing the below-described adhesion accelerating agent SC) into the film deposition chamber 60 and treats the surface of the wafer W with the adhesion accelerating agent gas.

The vaporizer 81 includes a retaining container 83, a gas inlet part 84, and a gas outlet part 85.

The retaining container 83 is configured to have the adhesion coupling agent SC (e.g., silane coupling agent) filled therein. A heating mechanism 86 is provided inside the retaining container 83. The adhesion coupling agent SC filled inside the retaining container 83 can be heated and vaporized by the heating mechanism 86. It is to be noted that a heater or the like may be used as the heating mechanism 86. As long as the retaining container 83 can be heated, the heating mechanism 86 can be arbitrarily positioned in a given part of the retaining container 83.

The gas inlet part 84 guides an adhesion accelerating agent carrier gas formed of an inert gas (e.g., nitrogen (N₂)) from an adhesion accelerating agent carrier gas feeding part 87, so that the adhesion accelerating agent gas can be carried by the adhesion accelerating agent carrier gas. The gas inlet part 84 includes a gas inlet tube 84a and a gas inlet port 84b. The gas inlet tube 84a is a tube for guiding the adhesion accelerating agent carrier gas from the outside to the inside of the retaining container 83. The gas inlet tube 84a is attached to a top surface of the retaining container 83 in a manner penetrating through the top surface of the retaining container 83 and extending vertically (i.e. from top to bottom of the retaining container 83) into the retaining container 83. Further, one end of the gas inlet tube 84a has an opening at the bottom part of the retaining container 83 whereas the other end of the gas inlet tube 84a is connected to the adhesion accelerating agent carrier gas feeding part 87 outside the retaining container 83. The gas inlet port 84b corresponds to the opening formed on the bottom end of the gas inlet tube 84a.

FIG. 5 illustrates the gas inlet port 84b positioned below the liquid surface of the adhesion accelerating agent SC for bubbling the adhesion accelerating agent SC with the adhesion accelerating agent carrier gas fed from the gas inlet port 84b. Alternatively, the gas inlet port 84b may be positioned above the liquid surface of the adhesion accelerating agent SC. In this case, the adhesion accelerating agent SC need not be bubbled with the adhesion accelerating agent carrier gas fed from the gas inlet port 84b.

The gas outlet part 85 guides the adhesion accelerating agent gas together with the adhesion accelerating agent carrier gas out from the retaining container 83. The gas outlet part 85 includes a gas outlet tube 85a and a gas outlet port 85b. The gas outlet tube 85a is a tube for guiding the adhesion accelerating agent gas and the adhesion accelerating agent carrier gas out from the retaining container 83. The gas outlet tube 85a is attached to the top surface of the retaining container 83 in a manner penetrating the top surface of the retaining container 83. Further, one end of the gas outlet tube 85a has an opening at an inner top part of the retaining container 83 whereas the other end of the gas outlet tube 85a is connected to a feeding tube 82 provided inside the film deposition chamber 60. The gas outlet port 85b corresponds to the opening formed on the bottom end of the gas outlet tube 85a.

The feeding tube 82, which is made of quartz, penetrates through the sidewall of the film deposition chamber 60 and bends in a manner extending upward. A feed opening 82a is formed at one end of the feeding tube 82 inside the film deposition chamber 60. The feeding tube 82 feeds the adhesion accelerating agent gas from the vaporizer 81 to the inside of the film deposition chamber 60 via the feed opening 82a. It is preferable for the feed opening 82a to be provided in one part in the film deposition chamber 60 in the vicinity of the wafer(s) W mounted on the boat 44. Thereby, the adhesion accelerating agent gas from the feed opening 82a can be evenly dispersed inside the film deposition chamber 60.

The purge gas feed mechanism 90 includes a purge gas feeding part 91 and a purge gas feeding tube 92. The purge gas feeding part 91 is connected to the film deposition chamber 60 via the purge gas feeding tube 92. The purge gas feeding part 91 feeds a purge gas into the film deposition chamber 60. A valve 93 and a mass flow controller (MFC) 94 are provided at a midsection of the purge gas feeding tube 92. The valve 93 is for communicating or disconnecting the purge gas feeding part 91 with respect to the inside of the film deposition chamber 60. The MFC 94 is for controlling the flow rate of the purge gas. Nitrogen (N₂) gas may be used as the purge gas.

The exhaust mechanism 95 includes an exhaust device 96 and an exhaust pipe 97. The exhaust mechanism 95 is configured to evacuate gas from the inside of the film deposition chamber 60 via the exhaust pipe 97.

The cleaning gas feed mechanism 100 includes a cleaning gas feeding part 101 and a cleaning gas feeding tube 102. The cleaning gas feeding part 101, which is connected to the film deposition chamber 60 via the cleaning gas feeding tube 102, feeds a cleaning gas into the film deposition chamber 60. A valve 103 and a mass flow controller (MFC) 104 are provided at a midsection of the cleaning gas feeding tube 102. The valve 103 is for communicating or disconnecting the cleaning gas feeding part 101 with respect to the inside of the film deposition chamber 60. The MFC 104 is for controlling the flow rate of the cleaning gas. Oxygen (O₂) gas may be used as the cleaning gas.

In this embodiment, the MFC 104 controls the flow rate of the cleaning gas fed from the cleaning gas feed mechanism 100, the MFC 94 controls the flow rate of the purge gas fed from the purge gas feed mechanism 90, and a valve (not illustrated) controls the flow rate of exhaust from the film deposition chamber 60. Thereby, an oxygen atmosphere can be generated inside the film deposition chamber 60 (generation of oxygen atmosphere) and the oxygen can be adjusted to a desired partial pressure.

The control part 110 includes, for example, a processing part, a storage part, and a display part, which are not illustrated in FIG. 4. The processing part is, for example, a computer including a central processing unit (CPU). The storage part is a computer-readable recording medium formed of, for example, hard disks, on which a program for causing the processing part to execute various processes is recorded. The display part is formed of, for example, a computer screen (display). The processing unit reads a program recorded in the storage part and transmits control signals to components of the boat 44a (substrate holding part), the heater 62, the cooling mechanism 65, the supply mechanism 70, the adhesion accelerating agent supply mechanism 80, the purge gas supply mechanism 90, the exhaust mechanism 95, and the cleaning gas feed mechanism 100 in accordance with the program, thereby executing the below-described film deposition process.

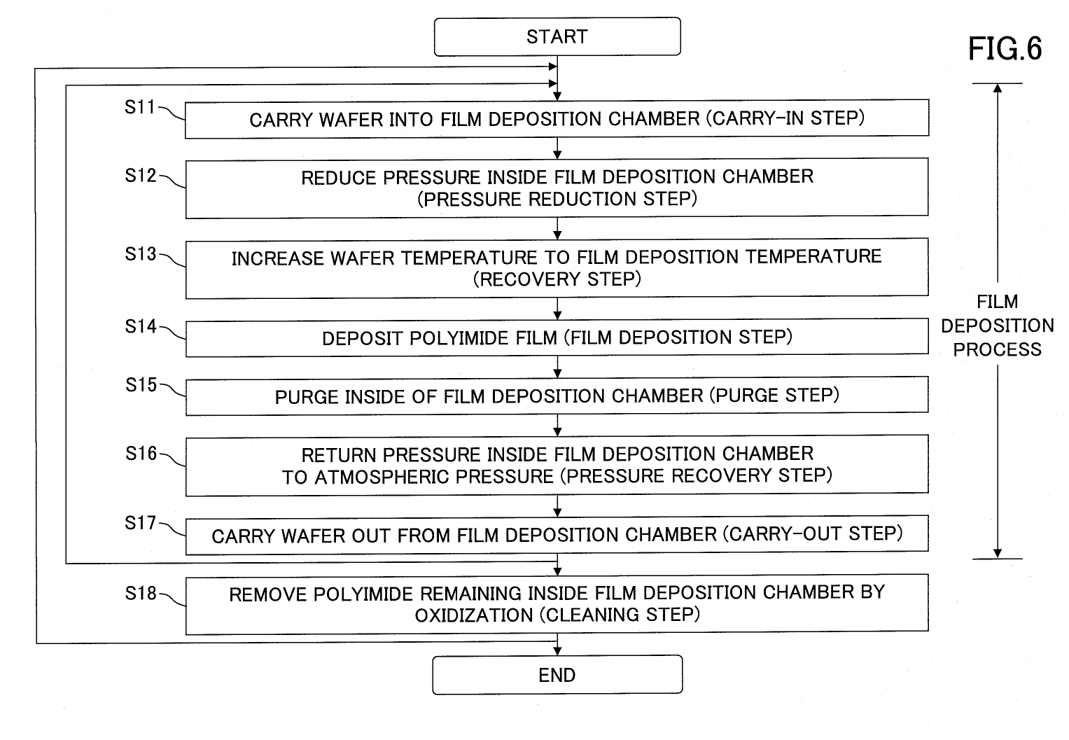

Next, a film deposition process using the above-described embodiment of the film deposition apparatus 10 is described. FIG. 6 is a flowchart for illustrating the processes of steps including a film deposition process using the film deposition apparatus 10 according to this embodiment.

After the start of a film deposition process, the wafers W are carried into the film deposition chamber 60 (Step S11, carry-in step). In the embodiment of the film deposition apparatus 10 illustrated in FIG. 1, in the loading area 20, the wafers W may be loaded into the boat 44a with the transfer mechanism 7 and the boat 44a loaded with the wafers W may be placed on the lid body 43 with the boat conveying mechanism 45c. Then, the lid body 43 on which the boat 44a is placed is caused to move upward by the elevation mechanism 46 to be inserted into the film deposition chamber 60, so that the wafers W are carried into the film deposition chamber 40.

Then, the internal pressure of the film deposition chamber 60 is reduced (Step S12, pressure reducing step). By controlling the exhaust capability of the exhaust device 96 or a flow regulating valve (not illustrated) provided between the exhaust device 96 and the exhaust pipe 97, the amount by which the film deposition chamber 60 is evacuated via the exhaust pipe 97 is increased. Thereby, an atmosphere containing no moisture is generated in the film deposition chamber 60. It is to be noted that the method for generating an atmosphere containing no moisture in the film deposition chamber 60 is not limited to the method of evacuating the film deposition chamber. That is, other methods may be used for generating the atmosphere containing no moisture in the film deposition chamber 60. Then, the internal pressure of the film deposition chamber 60 is reduced from, for example, a predetermined pressure (e.g., atmospheric pressure (101325 Pa)) to 39.9966 Pa.

Then, the temperature of the wafer(s) W is increased to a predetermined temperature (film deposition temperature) for depositing a polyimide film on the wafer W (Step S13, recovery step). After the boat 44a is carried into the film deposition chamber 60, the wafer(s) W mounted on the boat 44a is heated to the film deposition temperature by supplying power to the heater 62.

Further, in the recovery step according to an embodiment of the present invention, the surface of the wafer W may be treated with an adhesion accelerating agent. In this case, the surface of the wafer W is treated by heating the wafer W with the heater 62 together with feeding an adhesion accelerating agent gas from the adhesion accelerating agent feed mechanism 80 to the inside of the film deposition chamber 60 and causing a reaction between the fed adhesion accelerating agent gas and the heated wafer W inside the atmosphere containing no moisture in the film deposition chamber 60 (surface treatment step).

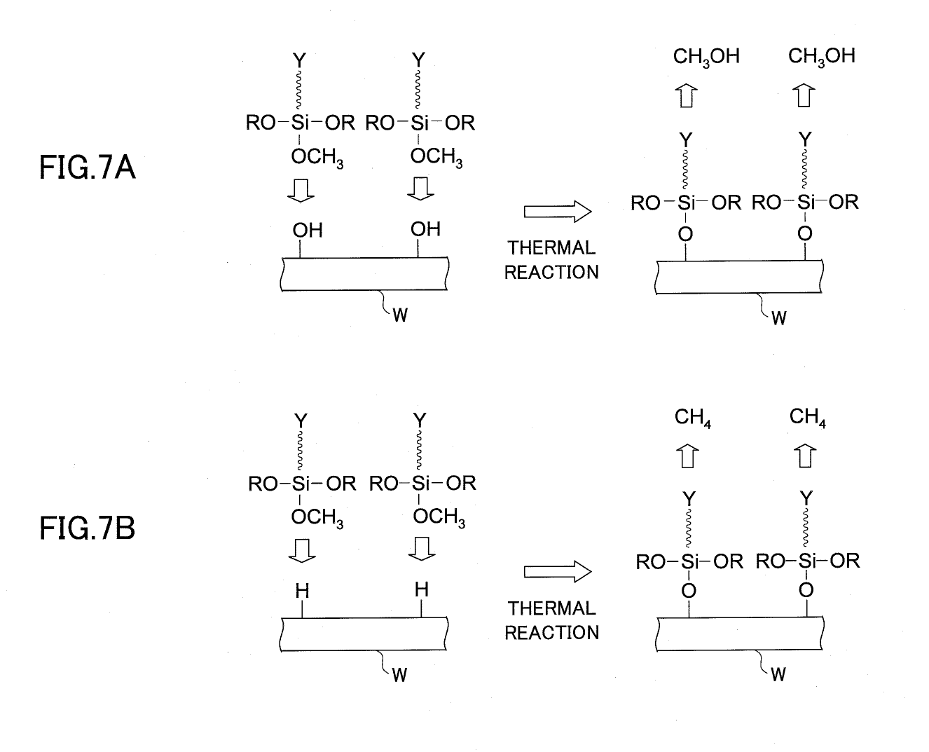

FIGS. 7A and 7B are schematic diagrams illustrating the reaction generated on the surface of the wafer W in a case where a silane coupling agent is used as the adhesion accelerating agent according to an embodiment of the present invention.

It is preferable to use organosilane having molecules containing an alkoxy group (RO— (R; alkyl group)) as the silane coupling agent. FIGS. 7A and 7B illustrate an example where organosilane having molecules containing, for example, a methoxy group (CH₃O—) is used. As illustrated in FIG. 7A, in a case of using a Si wafer having a hydroxyl group (—OH) terminated surface, methanol (CH₃OH) is generated by a thermal reaction between the methoxy group of the silane coupling agent and the hydroxyl group of the wafer surface. Thereby, the silane coupling agent adheres to the wafer surface. As illustrated in FIG. 7B, in a case of using a Si wafer having a hydrogen (H) terminated surface, methane (CH₄) is generated by a thermal reaction between the methoxy group of the silane coupling agent and the hydrogen atoms of the wafer surface. Thereby, the silane coupling agent adheres to the wafer surface.

N-phenyl-γ-aminopropyltrimethoxysilane (hereinafter also referred to as “SC agent A”) illustrated in the following chemical formula (1) may be used as the organosilane.

[Chemical Formula (1)]

(CH₃O)₃SiC₃H₅NHC₆H₅ (1)

Alternatively, γ-glycidoxypropyltrimethoxysilane (hereinafter also referred to as “SC agent B”) illustrated in the following chemical formula (2) may be used as the organosilane.

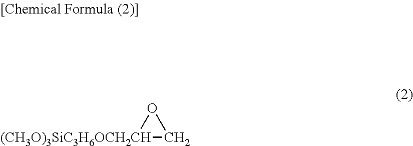

Among the aforementioned SC agents, it is more preferable to use the SC agent A. Even in a case of using a Si wafer having a surface terminated with hydrogen (H), the adhesive property of the polyimide film on the Si wafer can be improved by using the SC agent A.

In the case of performing the recovery step along with the surface treatment step, the vaporizer 81 vaporizes an adhesion accelerating agent including, for example, the SC agent A or the SC agent B and feeds the vaporized adhesion accelerating agent (adhesion accelerating agent gas) into the film deposition chamber 60 via the feed opening 82a formed in the feeding tube 82. In a case where the SC agent A, for example, is used, a vaporization rate of 0.3 g/minute can be attained by heating the retaining container 83 to, for example, 150° C. with a heating mechanism 86 (described below with reference to Table 1). Further, in a case where the SC agent B, for example, is used, a vaporization rate of 0.3 g/minute can be attained by heating the retaining container 83 to, for example, 100° C. with a heating mechanism 86. In this case, N2 gas, which is an adhesion accelerating agent carrier gas, may be introduced at a flow rate of 0.1 slm.

Next, a polyimide film is deposited (Step S14, film depositing step).

A first flow rate F1 at which the first source gas (PMDA gas) is caused to flow to the feeding tube 73a and a second flow rate F2 at which the second source gas (ODA gas) is caused to flow to the inner feeding tube 73b are determined in advance by the control part 110. The first source gas is caused to flow from the first source gas feeding part 71a to the feeding tube 73a at the determined first flow rate F1 and the second source gas is caused to flow from the second source gas feeding part 71b to the inner feeding tube 73b at the determined second flow rate F2 while the wafers W are being rotated by the rotation mechanism 49. Thereby, the first and the second source gases are mixed at a predetermined mixture ratio and fed into the film deposition chamber 60. PMDA and ODA are subjected to a polymerization reaction on the top surfaces of the wafers W so that a polyimide film is deposited on the top surfaces of the wafers W. Specifically, for example, the first flow rate F1 may be 900 sccm and the second flow rate F2 may be 900 sccm.

The polymerization reaction of PMDA and ODA at this point follows the following chemical formula (3).

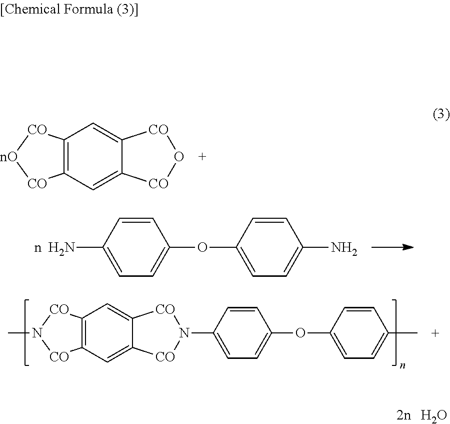

Then, the feeding of PMDA gas from the first source gas feeding part 71a and the feeding of ODA gas from the second source gas feeding part 71b are stopped, and the inside of the film deposition chamber 60 is purged with purge gas (Step S15, purge step).

More specifically, the feeding of the first source gas from the first source gas feeding part 71a is stopped by closing the valve 71c. Further, the feeding of the second source gas from the second source gas feeding part 71b is stopped by closing the valve 71d. Further, purge gas replaces the source gases inside the film deposition chamber 60 by controlling the purge gas feed mechanism 90 and the exhaust mechanism 95.

For example, by controlling the exhaust capability of the exhaust device 96 or adjusting a flow rate adjustment valve (not illustrated) provided between the exhaust device 96 and the exhaust pipe 97, the amount by which the film deposition chamber 60 is evacuated can be increased. Thereby, the pressure inside the film deposition chamber 60 can be reduced to, for example, 39.9966 Pa. Then, the valve 93 is opened and purge gas is fed inside the film deposition chamber 60 from the purge gas feed mechanism 90 until the internal pressure inside the film deposition chamber 60 reaches, for example, 666.61 Pa. Thereby, the source gases inside the film deposition chamber 60 can be replaced with purge gas. In addition, after performing decompression of the exhaust mechanism 95 and feeding of purge gas from the purge gas feed mechanism 90 once, respectively, the decompression of the exhaust mechanism 95 and the feeding of purge gas may be performed for a further number of times. Thereby, the source gases inside the film deposition chamber 60 can be more positively replaced with purge gas.

According to an embodiment of the present invention, the polyimide film deposited on the wafer W may be thermally treated by a heater in the purge step. The thermal treatment is performed for imidizing parts of the deposited film that are not imidized after the film deposition step. Because polyimide has a high insulating property, the insulating property of the deposited polyimide film can be improved by increasing the imidization rate (i.e. proportion of polyimide in the deposited film).

Then, the internal pressure of the film deposition chamber 60 is returned to an atmospheric pressure (Step S16, pressure recovery step). By controlling the exhaust capability of the exhaust device 96 or the flow regulating valve (not illustrated) provided between the exhaust device 96 and the exhaust pipe 97, the amount by which the film deposition chamber 60 is evacuated is reduced. The internal pressure of the film deposition chamber 60 is returned from, for example, 39.9966 Pa to, for example, an atmospheric pressure (101325 Pa).

As long as the thermal process of the deposited polyimide film is performed inside the film deposition chamber 60 before the below-described carry-out step, the thermal process may be performed during the recovery step or after the recovery step.

Then, the wafers W are carried out of the film deposition chamber 60 (Step S17, carry-out step). In the case of the film deposition apparatus 10 illustrated in FIG. 1, for example, the lid body 43 on which the boat 44a is placed may be caused to move downward by the elevation mechanism 46 to be carried out from inside the film deposition chamber 60 to the loading area 40. Then, the wafers W are transferred from the boat 44a placed on the carried-out lid body 43 to the container 21 by the transfer mechanism 47. Thereby, the wafers W are carried out of the film deposition chamber 60.

In the case of successively subjecting multiple batches to a film deposition process, a further transfer of the wafers W from the container 21 to the boat 44 is performed in the loading area 40 by the transfer mechanism 47, and the process returns again to Step S11 to subject the next batch to a film deposition process.

Accordingly, a film deposition process can be performed on a batch of substrates by performing Step S11 (carry-in step) through Step S17 (carry-out step). It is to be noted that Step S11 through Step S17 may be referred to as a film depositing process according to an embodiment of the present invention.

Then, the polyimide remaining inside the film deposition chamber 60 is removed by oxidization (Step S18, cleaning step).

As described above, a cleaning gas containing oxygen gas is fed into the film deposition chamber 60 from the cleaning gas feed mechanism 100. When feeding the cleaning gas, the MFC 104 controls the flow rate of the cleaning gas fed from the cleaning gas feed mechanism 100, the MFC 94 controls the flow rate of the purge gas fed from the purge gas feed mechanism 90, and the valve (not illustrated) controls the flow rate of exhaust from the film deposition chamber 60. Thereby, an oxygen atmosphere can be generated inside the film deposition chamber 60 (generation of oxygen atmosphere) and the oxygen can be adjusted to a desired partial pressure.

In a state where an oxygen atmosphere is generated inside the film deposition chamber 60, the film deposition chamber 60 is heated by the heater 62. By heating the film deposition chamber 60 to a temperature ranging from 360° C. to 540° C., the polyimide remaining inside the film deposition chamber 60 (including the polyimide film adhered to the inside of the film deposition chamber 60 and the polyimide film peeled off from the film deposition chamber 60) is removed by oxidization. Thereby, the polyimide remaining inside the film deposition chamber 60 can be prevented from carbonizing due to thermal decomposition as described below.

It is preferable to heat the film deposition chamber 60 with the heater 62 in a state where the oxygen atmosphere generated inside the film deposition chamber 60 has a partial pressure of oxygen that is equal to or greater than 20265 Pa. In this state, it becomes easier to oxidize the polyimide remaining in the film deposition chamber 60. Thus, carbonization due to thermal decomposition can be prevented more effectively.

In a case of repeating the film depositing process (Steps S11 to S17) for multiple times, the film depositing process (Steps S11 to S17) and the cleaning process (Step S18) can be performed alternately. Thereby, the polyimide remaining in the film deposition chamber 60 can always be removed by oxidization before the next film depositing process is performed.

Alternatively, the cleaning process (Step S18) may be performed once whenever the film depositing process (Steps S11 to S17) is repeatedly performed for a predetermined number of times. The predetermined number of times for repeatedly performing the film depositing process is set so that the number of particles adhered to the wafer prior to the cleaning process does not exceed a predetermined value. Thereby, the time for performing film deposition can be reduced while cleaning the inside of the film deposition chamber 60.

Accordingly, after the film depositing process and the cleaning process are finished, the film deposition process ends.

Next, the mechanism in which the cleaning method can prevent carbonization of polyimide and remove polyimide remaining inside the film deposition chamber is described.

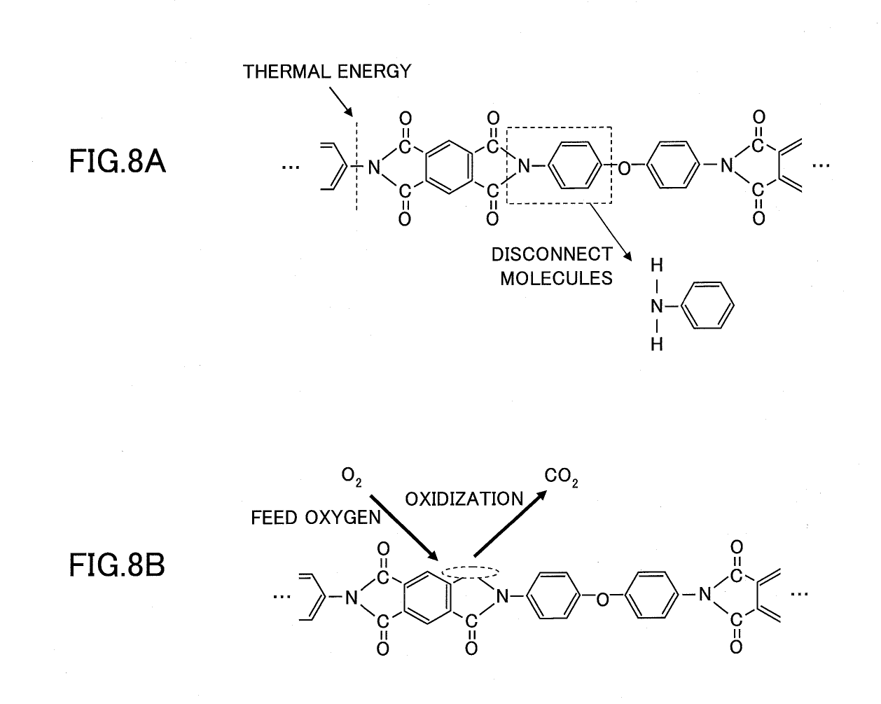

FIG. 8A illustrates the manner in which polyimide is thermally decomposed. FIG. 8B illustrates the manner in which polyimide is oxidized.

First, it is assumed that the film deposition chamber 60 is heated with the heater 62 in a state where no oxygen atmosphere is generated inside the film deposition chamber 60 (e.g., a state where a nitrogen atmosphere is generated inside the film deposition chamber 60). In this state, as illustrated in FIG. 8A, the chemical bond at various parts in the molecules of polyimide is disconnected by thermal energy. Thereby, the polyimide is thermally decomposed. During the thermal decomposition, a portion of carbon atoms inside the molecules of polyimide is carbonized and remain in the form of soot.

On the other hand, it is assumed that the film deposition chamber 60 is heated with the heater 62 in a state where an oxygen atmosphere is generated inside the film deposition chamber. In this state, as illustrated in FIG. 8B, the carbon atoms inside the molecules of polyimide chemically combines with oxygen, that is, the carbon atoms inside the molecules of polyimide are oxidized and vaporized into, for example, carbon dioxide (CO₂). As a result, polyimide is removed.

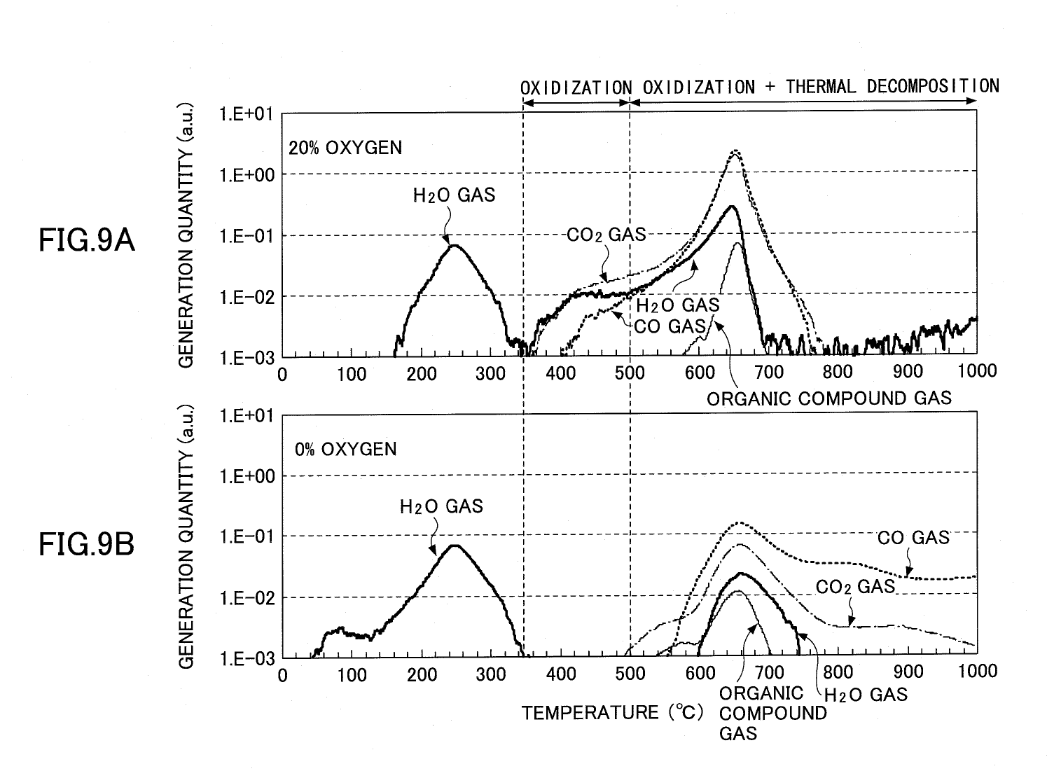

FIGS. 9A and 9B are graphs illustrating the results of measuring the quantity of a generated gas (generation quantity) by using a mass spectrometry (MS) method in a case of using a Temperature Programmed Desorption (TPD) method where the gas is desorbed (generated) by increasing the temperature of polyimide. The graph of FIG. 9A illustrates the results in a case where the partial pressure of oxygen is 20% (20265 Pa), and the graph of FIG. 9B illustrates the results in a case where the partial pressure of oxygen is 0% (0 Pa).

As illustrated in FIG. 9B, in a case where the partial pressure oxygen is 0% (0 Pa), generation of carbon dioxide (CO₂) begins when the heating temperature increases to 490° C., and generation of a gas considered to contain an organic compound (e.g., aniline or phenol) (hereinafter also referred to as “organic compound gas”) begins when the heating temperature increases to 540° C. Further, the generation quantity of CO₂ gas and carbon monoxide (CO) gas is relatively small with respect to the generation quantity of the organic compound gas. These conditions of FIG. 9B are conditions that cause soot-like particles to remain inside the film deposition chamber 60 after the cleaning step, that is, conditions that cause thermal decomposition of polyimide.

On the other hand, as illustrated in FIG. 9A, in a case where partial pressure of oxygen is 20% (20265 Pa), generation of carbon dioxide (CO₂) begins when the heating temperature increases to 360° C., and generation of an organic compound gas does not begin until the heating temperature increases to 580° C. Further, the generation quantity of CO₂ gas and carbon monoxide (CO) gas is relatively small with respect to the generation quantity of the organic compound gas.

Further, even in a case where partial pressure of oxygen is greater than 20%, substantially the same results as those of FIG. 9A are obtained. Accordingly, polyimide can be removed by oxidization without causing thermal decomposition of organic compounds by heating polyimide in a temperature ranging from 360° C. to 540° C. in a state where an oxygen atmosphere having a partial pressure of oxygen of 20% (20265 Pa).

However, conditions other than those described above may also be applied because the range of temperature depends on, for example, the configuration of the film deposition chamber 60 and/or the conditions for depositing the polyimide film. For example, even in a case where the heating temperature ranges from 540° C. to 700° C., polyimide can be removed by oxidization without causing thermal decomposition of organic compounds by performing the heating in a state where the partial pressure of oxygen is 40% (40530 Pa).

It is preferable for the partial pressure of oxygen to be 100% (101325 Pa). Thereby, polyimide can be removed by oxidization without making the internal pressure of the film deposition chamber 60 greater than atmospheric pressure.

Further, even in the above-described case of treating the surface of the wafer W with the adhesion accelerating agent, polyimide and the adhesion accelerating agent can be removed by oxidization without any particles remaining in the film deposition chamber 60.

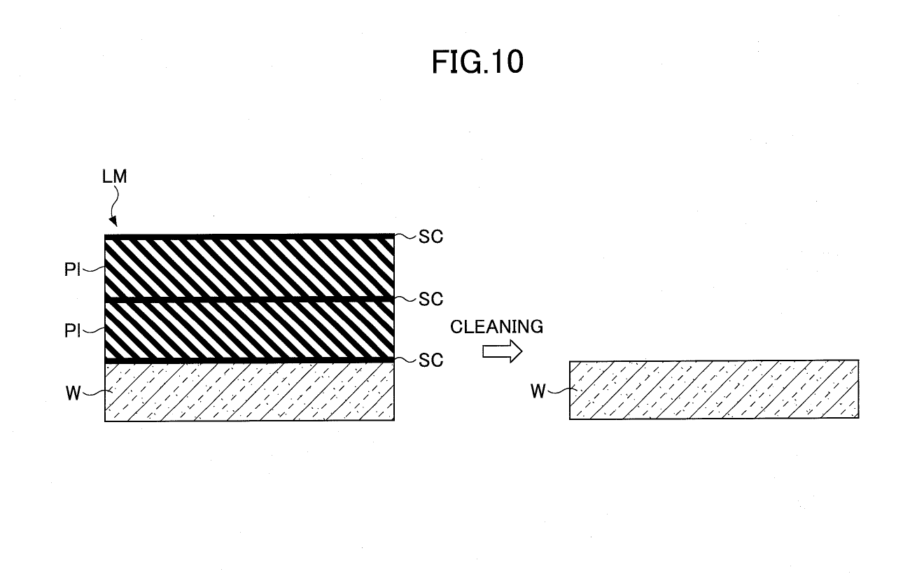

Next, it is evaluated whether the cleaning method according to an embodiment of the present invention can achieve removal by oxidization with respect to a layered member having plural layers of an adhesion accelerating agent SC and a polyimide film PI formed by performing film deposition for multiple times. A layered member LM having plural layers of the adhesion accelerating agent SC and the polyimide film PI is formed on a wafer W instead of a film deposition chamber and is used as a sample of the evaluation. FIG. 10 is a cross-sectional view illustrating a state before and after performing the cleaning process on the wafer W having the layered member LM formed thereon.

For example, in a state where a Si wafer W is retained in a temperature of 200° C., surface treatment is performed on the Si wafer W by heating the above-described SC agent A to 150° C. and feeding the SC agent A to the. Si wafer W at a flow rate of 0.3 g/minute for 600 seconds. Then, a polyimide film PI having a thickness of 250 nm is formed on the surface-treated wafer W. Then, a surface treatment, process using an adhesion accelerating agent, a process of depositing a polyimide film, and a further surface treatment process using an adhesion accelerating agent are repeatedly performed in this order. Thereby, the wafer having the layered member LM is obtained as illustrated in the left side of FIG. 10.

Then, the flow rate of oxygen gas and the flow rate of exhaust gas from the film deposition chamber 60 are adjusted for the wafer W so that the partial pressure of oxygen becomes 100% (101325 Pa). For example, the flow rate of the oxygen gas is adjusted to 30 slm. Then, a cleaning process is performed in a temperature of 700° C. for 120 minutes. As a result, it is confirmed that no particles or the like remain by observing the surface of the wafer W with a scanning electron microscope after performing the cleaning process.

Accordingly, with the above-described first embodiment of the film deposition apparatus for depositing a polyimide film, polyimide remaining in a film deposition chamber can be removed by oxidization by heating the film deposition chamber with a heating mechanism in a state where an oxygen atmosphere is generated inside the film deposition chamber. Thereby, polyimide along with an adhesion accelerating agent can be removed without any particles remaining in the film deposition chamber. Further, polyimide and an adhesion accelerating agent can be removed without any particles remaining in the film deposition chamber with respect to a layered member formed by repeatedly performing a process of depositing a polyimide film and a surface treatment process using the adhesion accelerating agent.

### Second Embodiment

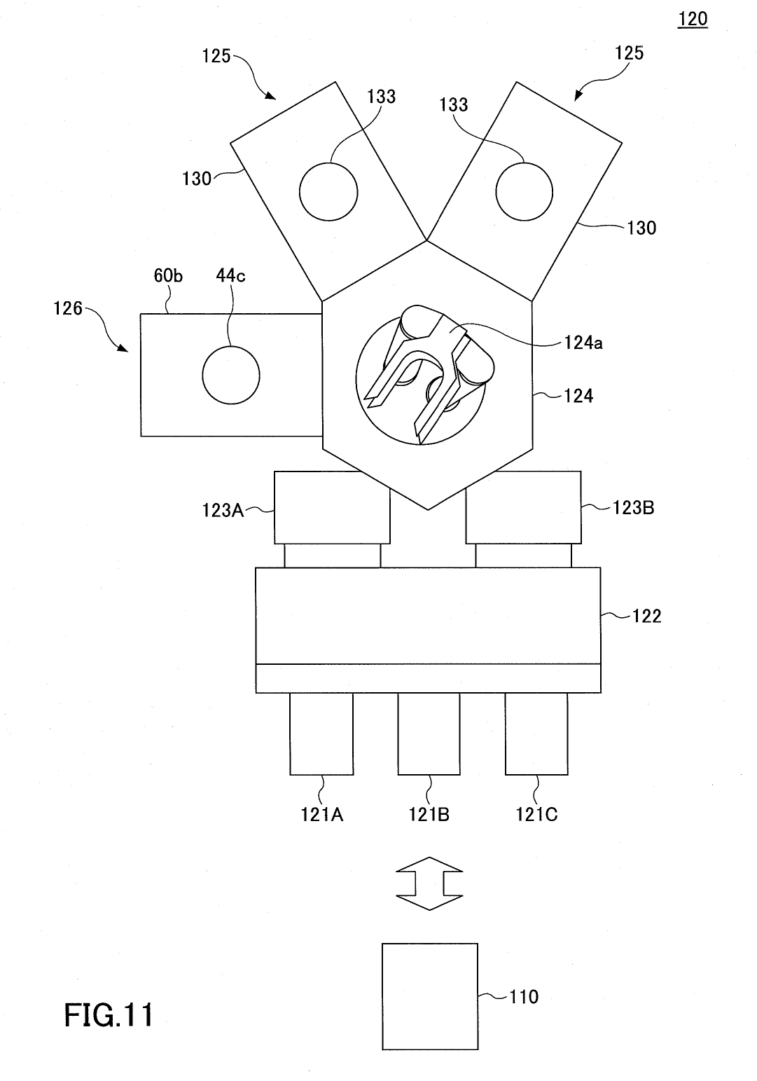

Next, a cleaning method and a film depositing method according a second embodiment of the present invention are described with reference to FIGS. 11-13.

As described below, unlike the cleaning method and the film depositing method of the first embodiment, the film deposition apparatus of the second embodiment includes a deposition container configured to perform single wafer processing and has a process chamber (for performing surface treatment) provided separately from the film deposition chamber.

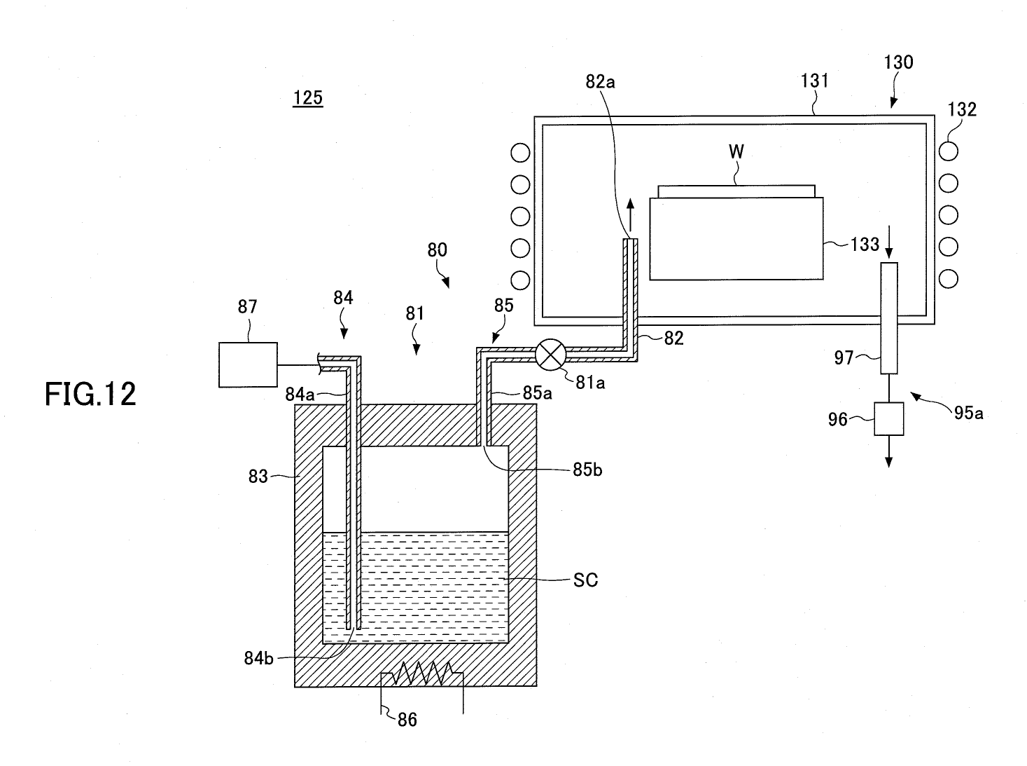

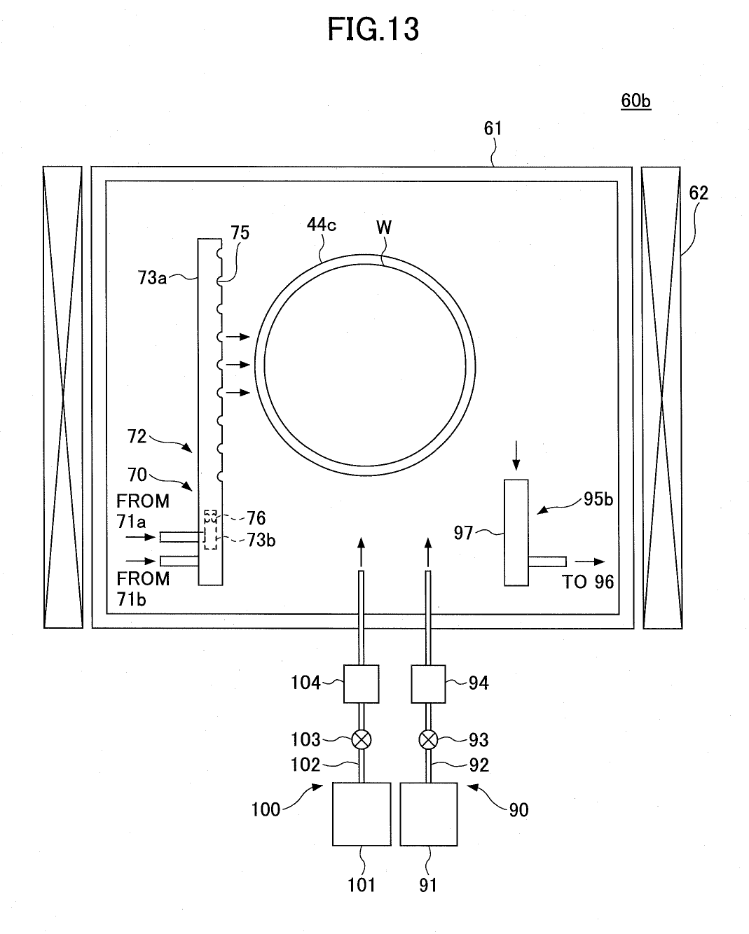

FIG. 11 is a plan view illustrating a film deposition apparatus 120 for performing the cleaning method and the film depositing method according to the second embodiment of the present invention. FIG. 12 is a front view illustrating the configurations of a process container 130, the adhesion accelerating agent feed mechanism 80, and an exhaust mechanism 95a according to the second embodiment of the present invention. FIG. 13 is a plan view illustrating the configurations of a film deposition chamber 60b, the feed mechanism 70, and the exhaust mechanism 95b according to the second embodiment of the present invention.

As illustrated in FIG. 11, the film deposition apparatus 120 includes ports 121A-121C, a loader 122, load locks 123A, 123B, a conveying chamber 124, plural surface treating parts 125, and a film depositing part 126.

The loader 122 is connected to the ports 121A-121C. The load locks 123A, 123B are connected to the loader 122. The conveying chamber 124 is connected to the load locks 123A, 123B. Two surface treating parts 125 and the film depositing part 126 are connected to the conveying chamber 124. The conveying chamber 124 includes a conveying arm 124a for conveying a wafer(s) between the load locks 123A, 123B, the surface treating parts 125, and the film depositing part 126.

It is to be noted that the number of the film depositing parts 125 and the film depositing parts 126 is not to be limited in particular and may be discretionarily changed according to surface treating conditions and film depositing conditions for improving throughput.

As illustrated in FIGS. 11 and 12, the surface treating part 125 includes the process container 130, the adhesion accelerating agent feed mechanism 80, and the exhaust mechanism 95a.

The adhesion accelerating agent feed mechanism 80 includes the vaporizer 81, and the feeding tube 82. Except for the feeding tube 82 being provided inside the process container 130, the adhesion accelerating agent feed mechanism 80 of the second embodiment is the same as the adhesion accelerating agent feed mechanism 80 of the first embodiment. The exhaust mechanism 95a includes the exhaust device 96 and the exhaust pipe 97 and has substantially the same configuration as the exhaust mechanism 95 provided in the film deposition chamber 60 of the first embodiment.

The process container 130 includes a process chamber 131, a heater (heating device) 132, a substrate holding part 133, and the exhaust mechanism 95a. The heater (heating device) 132 is for heating the wafer W when performing surface treatment on the wafer W. The substrate holding part 133 is for holding the wafer W. The substrate holding part 133 is configured to hold a single wafer W. The heater (heating device) 132 may be provided inside the substrate holding part 133.

As illustrated in FIG. 13, the film depositing part 126 includes the film deposition chamber 60b, the feed mechanism 70, the purge gas feed mechanism 90, the exhaust mechanism 95b, and the cleaning gas feed mechanism 100. The purge gas feed mechanism 90 of the second embodiment has substantially the same configuration as that of the purge gas feed mechanism of the first embodiment and includes the purge gas feeding part 91, the purge gas feeding tube 92, the valve 93, and the MFC 94. The exhaust mechanism 95b of the second embodiment has substantially the same configuration as that of the exhaust mechanism 95 of the first embodiment and includes the exhaust device 96 and the exhaust tube 97. The cleaning gas feed mechanism 100 of the second embodiment has substantially the same configuration as that of the cleaning gas feed mechanism of the first embodiment and includes the cleaning gas feeding part 101, the cleaning gas feeding tube 102, the valve 103, and the MFC 104.

The film deposition chamber 60b includes a reaction chamber 61, a heater (heating device) 62, and a substrate holding part 44c. The substrate holding part 44c is configured to hold a single wafer W.

The feed mechanism 70 includes the first source gas feeding part 71a, the second source gas feeding part 71b, and the injector 72. The first and the second source gas feeding parts 71a, 71b of the second embodiment have substantially the same configurations as those of the first embodiment.

The injector 72 includes the feeding tube 73a and the inner feeding tube 73b. The source gas feeding part 71 is connected to the feeding tube 73a of the injector 72. Other than the feeding tube 73a and the inner feeding tube 73b being arranged in a manner extending in a horizontal direction, the injector 72 of the second embodiment has substantially the same configuration as that of the first embodiment. That is, plural feed openings 75 are formed in the feeding tube 73a. Further, the opening(s) 76 may be formed in the vicinity of a downstream side of the inner feeding tube 73b for feeding the first source gas to the inner space of the feeding tube 73a.

It is to be noted that FIG. 13 illustrates an example where the first source gas is fed from the first source gas feeding part 71a to the inner feeding tube 73b and the second source gas is fed from the second source gas feeding part 71b to the feeding tube 73a. Alternatively, the first source gas may be fed to the feeding tube 71b and the second source gas may be fed to the inner feeding tube 73b.

The control part 110 of the second embodiment has substantially the same configuration as that of the first embodiment.

In the film deposition process of the second embodiment, the surface of the wafer W is treated with the adhesion accelerating agent by the surface treating part 125 before the film depositing part 126 performs film deposition.

The conveying arm 124a of the conveying chamber 124 transfers the wafer W to the substrate holding part 133 provided inside the process container 130 of the surface treating part 125. Then, the exhaust mechanism 95a decompresses the inside of the process container 130.

Then, by controlling the power supplied to the heater 132 with the control part 110, the temperature of the wafer W is increased to a treatment temperature for treating the surface of the wafer W. Then, while the wafer W is being heated, the adhesion accelerating gas fed into the process container 130 and the heater wafer W are made to react to each other inside an atmosphere containing no moisture, so that the surface of the wafer W is treated (surface treatment step).

In the above-described modified examples, it is preferable to use a silane coupling agent as the adhesion accelerating agent. An organosilane having molecules containing an alkoxy group may be used as the silane coupling agent in modified examples. It is preferable to use SC agents A and B (see above-described chemical formulas 1 and 2) as the organosilane. Further, in a case of using the SC agent A, the SC agent A can be used in a state where the Si wafer is terminated with hydrogen atoms (H). Thereby, the adhesive property of the deposited polyimide film can be improved.

Accordingly, after performing surface treatment with the adhesion accelerating agent by using the surface treating part 125, the film depositing part 126 performs film deposition. Except for the film deposition of the film deposition part 126 being performed by single-wafer process instead of a batch process, the film deposition step of the second embodiment is substantially the same as the film deposition step of the first embodiment.

Then, in the second embodiment, the polyimide remaining inside the film deposition chamber 60b is removed by oxidization (cleaning step).

Similar to the first embodiment, a cleaning gas containing oxygen gas is fed into the film deposition chamber 60b from the cleaning gas feed mechanism 100. When feeding the cleaning gas, the MFC 104 controls the flow rate of the cleaning gas fed from the cleaning gas feed mechanism 100, the MFC 94 controls the flow rate of the purge gas fed from the purge gas feed mechanism 90, and the valve (not illustrated) controls the flow rate of exhaust from the film deposition chamber 60b. Thereby, an oxygen atmosphere can be generated inside the film deposition chamber 60b (generation of oxygen atmosphere) and the oxygen can be adjusted to a desired partial pressure.

In a state where an oxygen atmosphere is generated inside the film deposition chamber 60b, the film deposition chamber 60b is heated by the heater 62. By heating the film deposition chamber 60b to a temperature ranging from 360° C. to 540° C., the polyimide remaining inside the film deposition chamber 60b (including the polyimide film adhered to the inside of the film deposition chamber 60b and the polyimide film peeled off from the film deposition chamber 60b) is removed by oxidization. Thereby, the polyimide remaining inside the film deposition chamber 60b can be prevented from carbonizing due to thermal decomposition as described below.

It is preferable to heat the film deposition chamber 60b with the heater 62 in a state where the oxygen atmosphere generated inside the film deposition chamber 60b has a partial pressure of oxygen that is equal to or greater than 20265 Pa. In this state, it becomes easier to oxidize the polyimide remaining in the film deposition chamber 60b. Thus, carbonization due to thermal decomposition can be prevented more effectively.

Accordingly, with the above-described second embodiment of the film deposition apparatus for depositing a polyimide film, polyimide remaining in a film deposition chamber can be removed by oxidization by heating the film deposition chamber with a heating mechanism in a state where an oxygen atmosphere is generated inside the film deposition chamber. Thereby, polyimide along with an adhesion accelerating agent can be removed without any particles remaining in the film deposition chamber.

Further, the present invention is not limited to these embodiments, but variations and modifications may be made without departing from the scope of the present invention.

What is claimed is:

1. A cleaning method for a film deposition apparatus that deposits a polyimide film conveyed into a film deposition chamber by feeding a first source gas formed of dianhydride and a second source gas formed of diamine into the film deposition chamber, the method comprising the steps of:
generating an oxygen atmosphere in the film deposition chamber; and
removing polyimide remaining in the film deposition chamber by heating the film deposition chamber at a temperature of 360° C. to 540° C. in the oxygen atmosphere and oxidizing the polyimide.

2. The cleaning method as claimed in claim 1,
wherein the step of generating the oxygen atmosphere includes generating an oxygen atmosphere having a partial pressure of oxygen equal to or greater than 20265 Pa in the film deposition chamber,
wherein the heating is performed in the oxygen atmosphere having the partial pressure of oxygen equal to or greater than 20265 Pa.

3. A film depositing method for depositing a film on at least a substrate by feeding source gases into a film deposition chamber, the method comprising the steps of:
performing a film depositing process including
conveying in the substrate to the film deposition chamber,
feeding an adhesion accelerating agent gas into the film deposition chamber,
treating a surface of the substrate with the adhesion accelerating agent gas,
depositing a polyimide film on the substrate by feeding a first source gas formed of dianhydride and a second source gas formed of diamine into the film deposition chamber, and
conveying out the substrate having the polyimide film deposited thereon from the film deposition chamber; and
performing a cleaning process including
generating an oxygen atmosphere in the film deposition chamber, and
removing polyimide remaining in the film deposition chamber by heating the film deposition chamber in the oxygen atmosphere and oxidizing the polyimide.

4. The method as claimed in claim 3, wherein the film depositing process and the cleaning process are performed alternately.

5. The method as claimed in claim 3, wherein the cleaning process is performed once after repeating the film depositing process a predetermined number of times.

6. The method as claimed in claim 3, wherein the conveying in of the substrate includes conveying in a substrate retaining part having a plurality of the substrates vertically accommodated therein to the film deposition chamber, wherein the conveying out of the substrate includes conveying out the substrate retaining part from the film deposition chamber.

7. The method as claimed in claim 3, wherein the heating includes heating the film deposition chamber to a temperature of 360° C. to 540° C.

8. The method as claimed in claim 3,
wherein the generating of the oxygen atmosphere includes generating an oxygen atmosphere having a partial pressure of oxygen equal to or greater than 20265 Pa in the film deposition chamber,
wherein the heating is performed in the oxygen atmosphere having the partial pressure of oxygen equal to or greater than 20265 Pa.
